(19) United States
(12) Patent Application Publication
(10) Pub. No.: US 2025/0359248 A1
(43) Pub. Date: Nov. 20, 2025

(54) STI PROTECTION LAYER FORMATION THROUGH IMPLANTATION AND THE STRUCTURES THEREOF

(71) Applicant: Taiwan Semiconductor Manufacturing Co., Ltd., Hsinchu (TW)

(72) Inventors: Sung-En Lin, Xionglin Township (TW); Chung-Ting Ko, Kaohsiung City (TW); Min-Chi Wang, Taipei City (TW); Tai-Chun Huang, Hsinchu (TW)

(21) Appl. No.: 19/282,623

(22) Filed: Jul. 28, 2025

Related U.S. Application Data
(63) Continuation of application No. 18/901,946, filed on Sep. 30, 2024.
(60) Provisional application No. 63/647,143, filed on May 14, 2024.

(51) Int. Cl. H10D 64/01; H01L 21/762; H10D 30/01; H10D 30/43; H10D 30/67; H10D 62/10; H10D 62/13; H10D 64/23; H10D 84/01; H10D 84/03; H10D 84/83

(52) U.S. Cl. CPC H10D 64/017; H01L 21/76224; H10D 30/014; H10D 30/43; H10D 30/6735; H10D 30/6757; H10D 62/121; H10D 62/151; H10D 64/251; H10D 84/013; H10D 84/038; H10D 84/83

(57) ABSTRACT

A method includes forming a shallow trench isolation region aside of a protruding fin. The protruding fin includes a first semiconductor nanostructure and a second semiconductor nanostructure. A doping process is performed to dope a dopant into a top portion of the shallow trench isolation region to form a protection layer. The method further includes forming a dummy gate stack over the protruding fin, removing a sacrificial layer in the protruding fin to leave a space between the first semiconductor nanostructure and the second semiconductor nanostructure, forming a disposable interposer in the space. The dummy gate stack is then removed, followed by an etching process to remove the disposable interposer using an etchant. In the etching process, the protection layer is exposed to the etchant. A replacement gate stack is then formed, wherein a portion of the replacement gate stack is filled in the space.

### PRIORITY CLAIM AND CROSS-REFERENCE

This application is a continuation of U.S. patent application Ser. No. 18/901,946, filed on Sep. 30, 2024 and entitled “STI PROTECTION LAYER FORMATION THROUGH IMPLANTATION AND THE STRUCTURES THEREOF,” which claims the benefit of the U.S. Patent Provisional Application No. 63/647,143, filed on May 14, 2024 and entitled “SEMICONDUCTOR DEVICE AND FORMATION METHOD THEREOF,” each application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B through 16A, 16B, and 16C illustrate the views of intermediate stages in the formation of transistors and STI protection layers in accordance with some embodiments.

FIG. 17 illustrates the schematic distribution profiles of dopants in accordance with some embodiments.

FIG. 18 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors, protection layers for protecting shallow trench isolation regions, and the methods of forming the same are provided. In accordance with some embodiments of the present disclosure, the formation of a GAA transistor adopts Disposable Oxide Interposing (DOI) processes, which includes forming and removing sacrificial layers comprising oxides. Since the sacrificial layers do not have enough etching selectivity relative to Shallow Trench Isolation (STI) regions, the STI regions may be undesirable recessed, causing the undesirable increase in effective capacitance Ceff between conductive features, and the undesirable increase of out fringe capacitance. A protection layer (also referred to as a hard mask) is thus formed through implantation and/or directional plasma treatment to prevent the STI regions from being recessed during the removal of the sacrificial layers.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

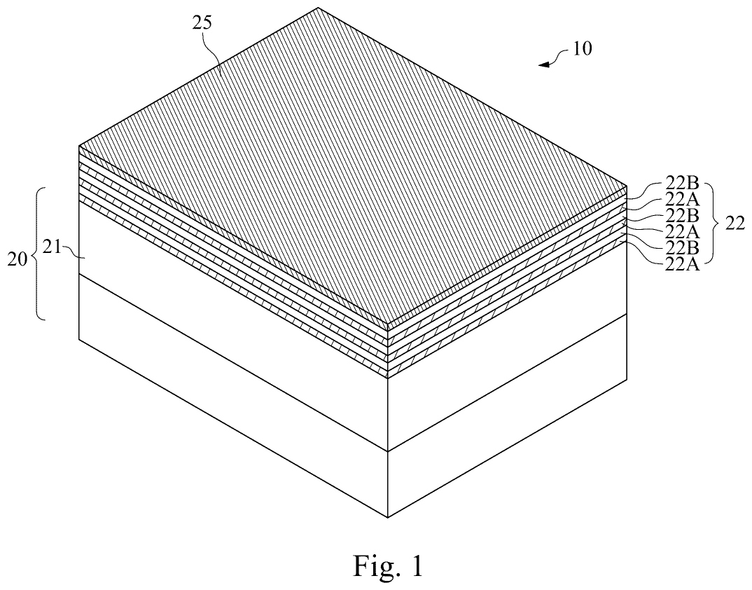

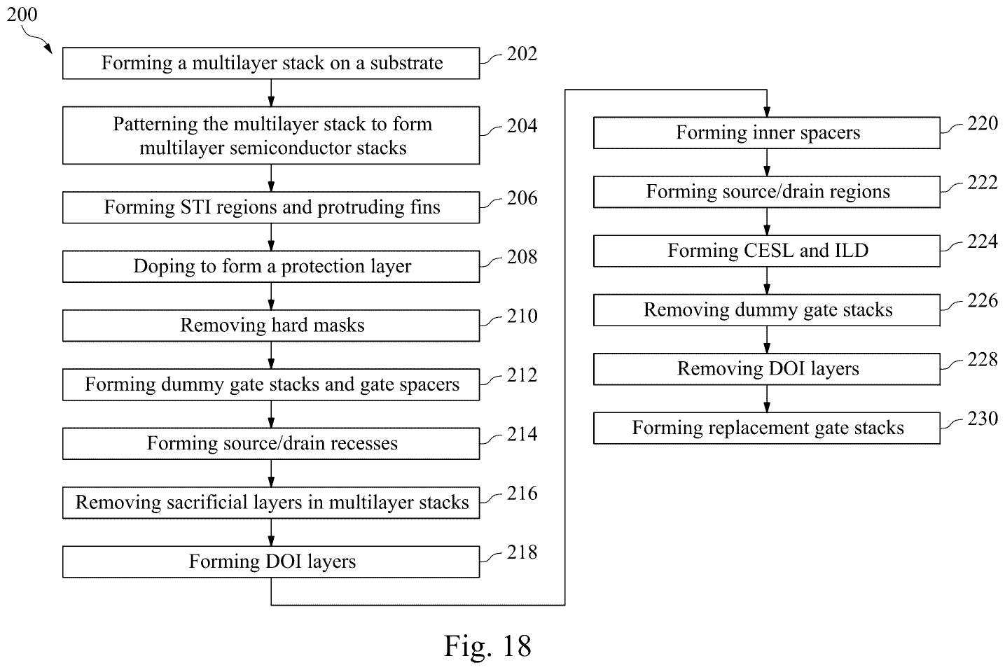

FIG. 1 through FIGS. 16A, 16B, and 16C illustrate the cross-sectional views of intermediate stages in the formation of a GAA transistor in accordance with some embodiments of the present disclosure. The corresponding processes are also reflected schematically in the process flow 200 as shown in FIG. 18.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 as shown in FIG. 18. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

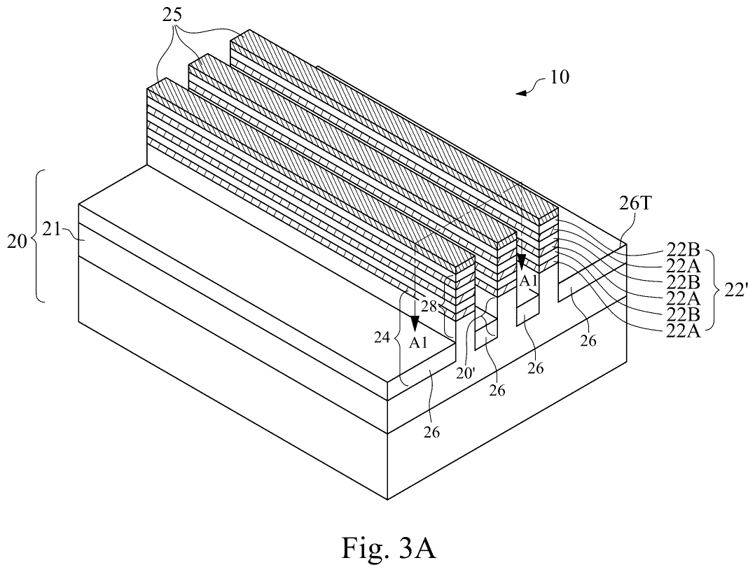

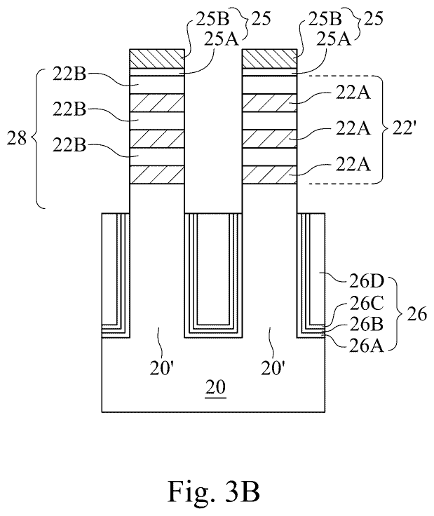

In accordance with some embodiments, mask layers 25 are formed. In accordance with some embodiments, mask layers 25 include pad oxide layer 25A (not shown in FIG. 1, refer to FIG. 3B) and hard mask layer(s) 25B formed over multilayer stack 22. In accordance with some embodiments, pad oxide layer 25A comprises silicon oxide, and hard mask layer 25B comprises silicon nitride, while other materials may be used.

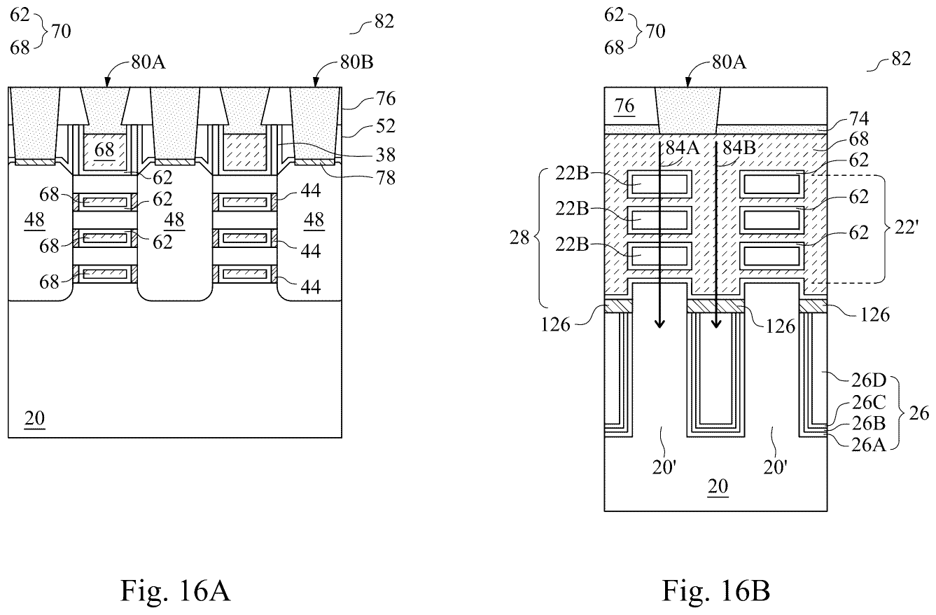

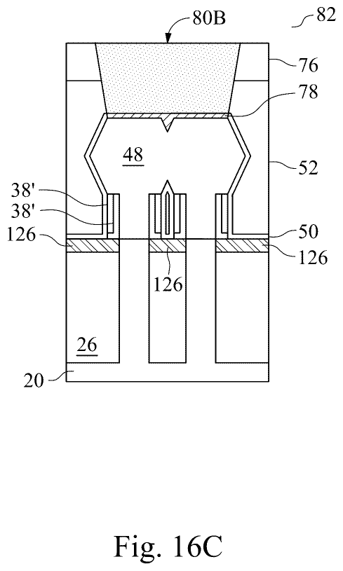

In accordance with some embodiments, a well implantation process may be performed to form well region 21, which may be p-type or n-type. The well region 21 has an opposite conductivity type than the subsequently formed source/drain regions 48 (FIGS. 16A and 16C). In accordance with alternative embodiments, the well implantation process may be performed in a later process, such as after the structure as shown in FIG. 3A is formed.

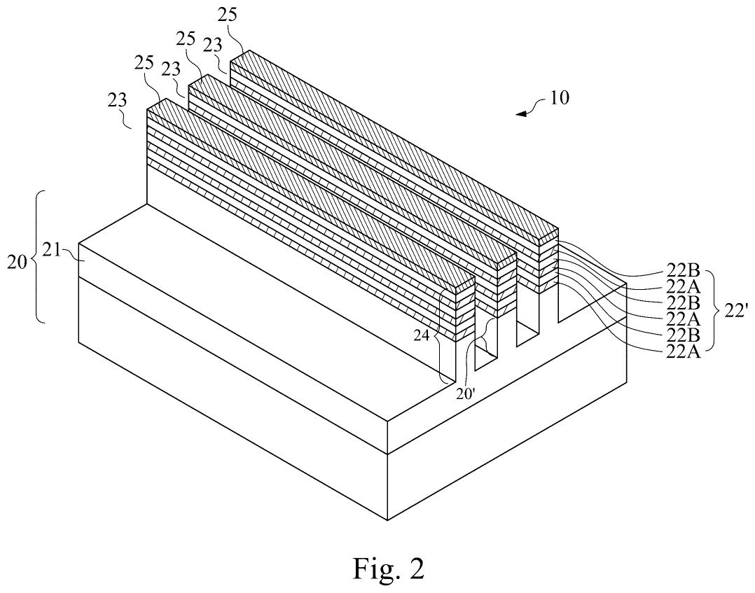

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 18. The formation of trenches 23 may include forming a patterned etching mask such as a patterned photoresist, and etching hard mask layer 25B to define patterns in hard mask layer 25B. The patterned hard mask layer 25B may then be used to etch the underlying pad oxide layer 25A, multilayer stack 22 and substrate 20 to form trenches 23.

Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

FIG. 3A illustrates the formation of isolation regions 26, which are also referred to as Shallow Trench Isolation (STI) regions throughout the description. The respective process is illustrated as process 206 in the process flow 200 as shown in FIG. 18. STI regions 26 may include a liner oxide (not shown), which may be a thermal oxide formed through the thermal oxidation of a surface layer of substrate 20, or may be deposited. The liner oxide may also be a deposited silicon oxide layer formed using, for example, ALD, High-Density Plasma Chemical Vapor Deposition (HDPCVD), CVD, or the like.

STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

FIG. 3B illustrates a cross-section A1-A1 in FIG. 3A. As shown in FIG. 3B, STI regions 26 may include a plurality of dielectric liners such as dielectric liners 26A, 26B, and 26C, and dielectric region 26D on dielectric liner 26C. In accordance with some embodiments, dielectric liner 26A is formed of or comprises silicon oxide, which may be formed through a thermal oxidation process or a deposition process. Dielectric liners 26B and 26C may be formed of silicon nitride, for example, while other materials may be used.

Dielectric region 26D may be formed of or comprise silicon oxide. Dielectric region 26D may have a lower density and a higher etching rate than dielectric liners 26A, 26B, and 26C. For example, when dielectric region 26D is formed of FCVD, spin-on coating, or the like, it may have a lower density than the dielectric liners 26A, 26B, and 26C. Dielectric region 26D may also be formed through another deposition process such as ALD, CVD, or the like.

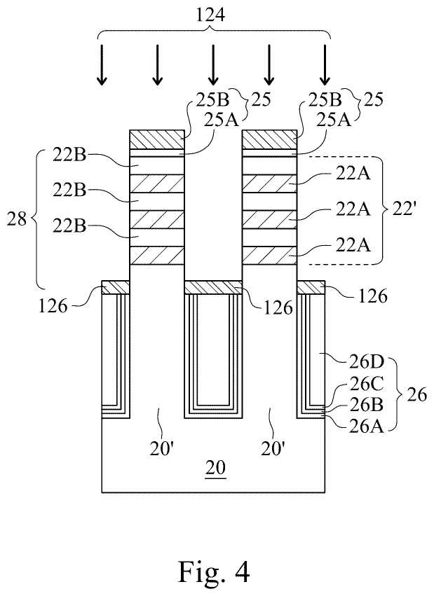

Referring to FIG. 4, a doping process 124 is performed. The respective process is illustrated as process 208 in the process flow 200 as shown in FIG. 18. The doped element (species) may include nitrogen, carbon, oxygen, and/or the like. For example, N₂, N₂O, CO₂, or the combination of N₂ and N₂O, may be used for doping. Inert gases such as Ar, He, and/or the like may also be used.

In accordance with alternative embodiments, a dopant that is a p-type dopant (such as boron and/or indium) or an n-type dopant (such as phosphorous, arsenic, antimony, or combinations thereof) may be doped. The conductivity type of the p-type or n-type dopant may be the same as the conductivity type of the dopant used for forming well region 21, and may be opposite to the conductivity type of the source/drain regions of the corresponding transistor. For example, when the subsequently formed source/drain regions 48 (FIGS. 16A and 16C) are p-type source/drain regions, the dopant introduced by the doping process 124 is of n-type. Conversely, when the subsequently formed source/drain regions 48 (FIGS. 16A and 16C) are n-type source/drain regions, the dopant introduced by the doping process 124 is of p-type.

In accordance with alternative embodiments, the p-type or n-type dopant introduced by doping process 124 has an opposite conductivity type than the well region 21, and thus has a same conductivity type as the subsequently formed source/drain region 48. In accordance with these embodiments, the concentration of the dopant is lower than the doping concentration in well region 21, so that the conductivity type of the well region 21 is not negated.

In accordance with some embodiments, the doping process 124 may be performed through a vertical implantation process and/or a plasma treatment process. The plasma treatment may be performed using the plasma generated through the above-recited gases.

As a result of the doping process 124, the top portions of STI regions 26 are converted to protection layer 126, which has a higher dopant (such as carbon, nitrogen, oxygen, and/or inert gas) concentration (and atomic percentages) than before the implantation process. The concentration and atomic percentages are also higher than the un-implanted portions of STI regions 26 such as the bottom portions of STI regions 26. Depending on the implanted species, the protection layer 126 may include SiOC, SiON, SiOCN, or the like, with other elements such as He, Ar, and/or the like may be incorporated. The thickness of protection layer 126 may be in the range between about 1 nm and about 20 nm.

In accordance with some embodiments in which implantation is adopted, the implantation energy is controlled, so that all or a majority of the implanted dopant is in the mask layers 25, and not in the underlying nanostructures 22B. In accordance with some embodiments, nanostructure 22B may be free from the dopant introduced by the doping process 124. In accordance with alternative embodiments, nanostructure 22B may include the dopant with low concentrations. The concentrations (atomic percentages) of the dopant are low enough so that the property of nanostructures 22B is not adversely changed.

In accordance with some embodiments, the dopant may be implanted with an energy in a range between about 1 keV and about 20 keV. The dosage of each of the above listed species and/or the total dosage of the implanted species may be in the range between about 5E13/cm² and 1E16/cm². The concentration of the dopant in the protection layer 126 may be in the range between about 1E20/cm³ and about 3E22/cm³.

When plasma treatment is performed, a low bias power may be provided, so that the dopant is directional and may diffuse vertically to a desirable depth, without diffusing too deep horizontally into multilayer stacks 22′ from the sidewalls of multilayer stacks 22′. In accordance with some embodiments, the bias power may be in the range between about 20 eV and about 120 eV.

In accordance with some embodiments, when the doping process 124 is performed, the sidewalls of multilayer stacks 22′ are exposed. In accordance with alternative embodiments, before the doping process 124, a conformal sacrificial layer may be formed on the structure shown in FIG. 4. After the doping process 124, the conformal sacrificial layer is removed, along with the dopant laterally diffused into the vertical portions of the conformal sacrificial layer. The vertical portions of the conformal sacrificial layer on the sidewalls of multilayer stacks 22′ thus act as a sacrificial layer to reduce the amount of the dopant from diffusing into multilayer stacks 22′ in sideway directions. The conformal sacrificial layer may be formed of or comprise a dielectric material different from the material of STI regions 26 and multilayer stacks 22′, and may comprises SiC, SiCN, or the like.

In accordance with some embodiments, the doping process 124 may be performed at a room temperature (in the range between about 18° C. and about 22° C., for example). In accordance with alternative embodiments, the doping process 124 may be performed at an elevated temperature such as in the range between about 18° C. and about 500° C.

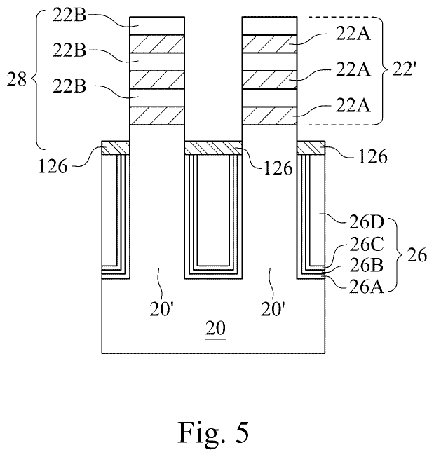

The mask layers 25 are then removed. The respective process is illustrated as process 210 in the process flow 200 as shown in FIG. 18. The resulting structure is shown in FIG. 5. Multilayer stacks 22′ and protection layer 126 are exposed.

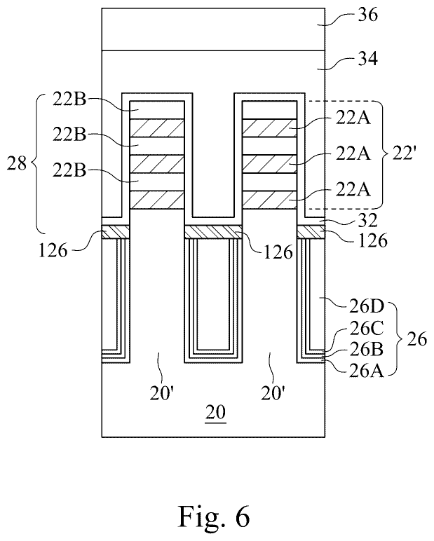

In subsequent processes, dummy gate stacks and gate spacers are formed. FIG. 6 illustrates the formation of dummy gate dielectric layer 32, dummy gate electrode layer 34, and hard mask layer 36. Dummy gate dielectric layer 32 may be formed by oxidizing the surface portions of protruding fins 28 to form oxide layers, or by depositing a dielectric layer such as a silicon oxide layer. Dummy gate electrode layer 34 may be formed, for example, by depositing polysilicon or amorphous silicon, and other materials such as amorphous carbon may also be used. A planarization process may be performed to level the top surface of dummy gate electrode layer 34.

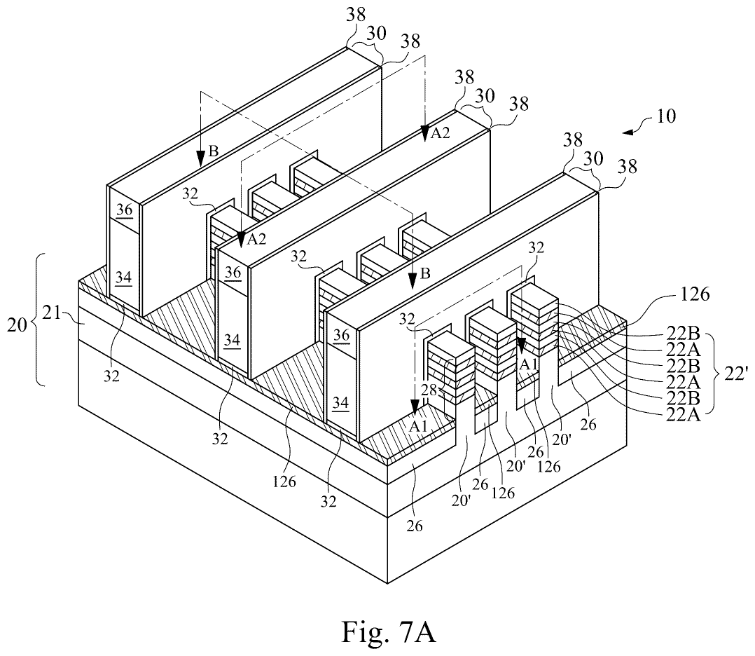

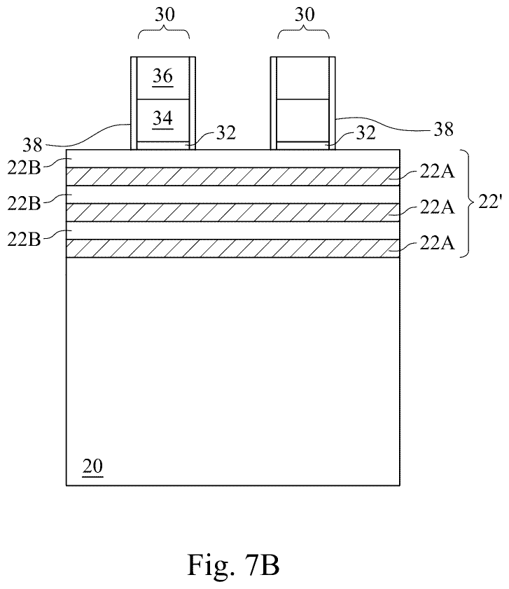

Hard mask layer 36 may be formed through deposition over gate electrode layer 34. Hard mask layer 36 may be formed of silicon nitride, silicon oxide, silicon carbo-nitride, silicon oxy-carbo nitride, or multilayers thereof. A patterning process(es) is then performed to pattern hard mask layer 36, dummy gate electrode layer 34, and dummy gate dielectric layer 32 to form a plurality of dummy gate stacks 30 as shown in FIG. 7A, which illustrates a perspective view of the structure. The respective process is illustrated as process 212 in the process flow 200 as shown in FIG. 18.

Next, as also shown in FIG. 7A, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

As show in FIG. 7A, protection layer 126 includes first portions that are directly under and overlapped by dummy gate stacks 30, and second portions that are not directly under (and are laterally offset from) dummy gate stacks 30. The thickness of the first portions may be the same as the second portions. FIG. 7B illustrates a cross-sectional view of the cross-section B-B as shown in FIG. 7A.

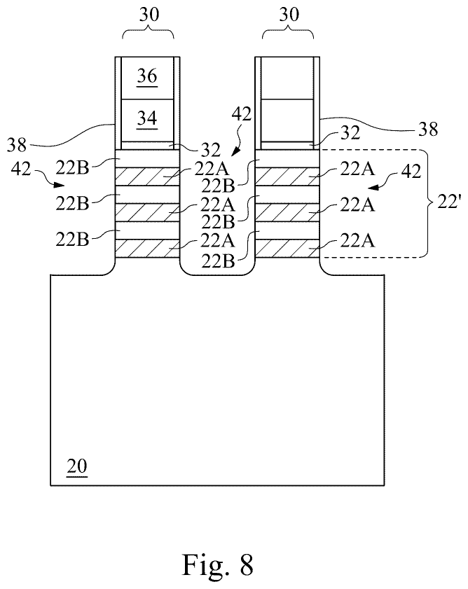

FIG. 8 illustrates a source/drain recessing process. The respective process is illustrated as process 214 in the process flow 200 as shown in FIG. 18. The protruding fins 28 that are not directly underlying dummy gate stacks 30 and gate spacers 38 are etched in an anisotropic etching process. Source/drain recesses 42 are thus formed.

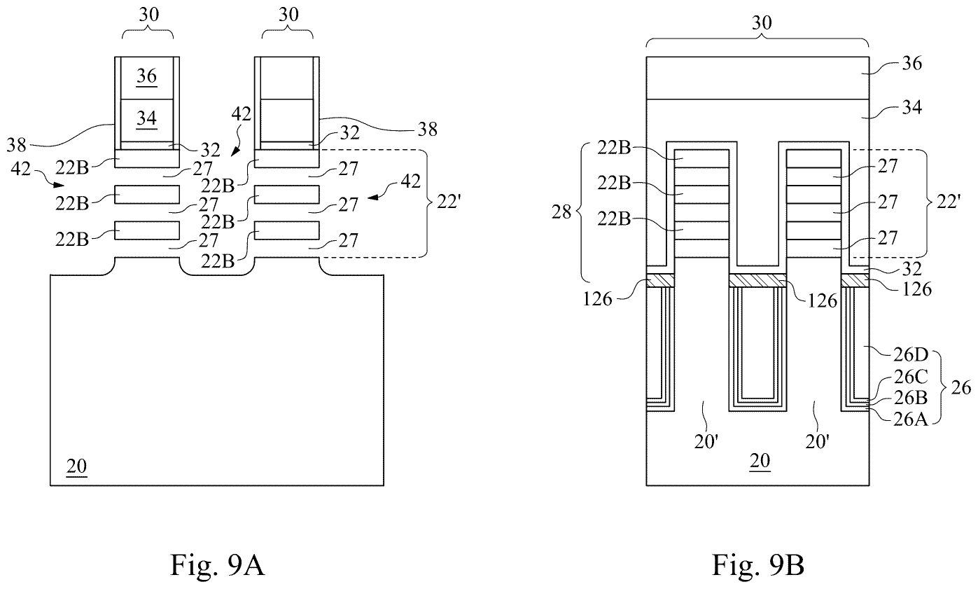

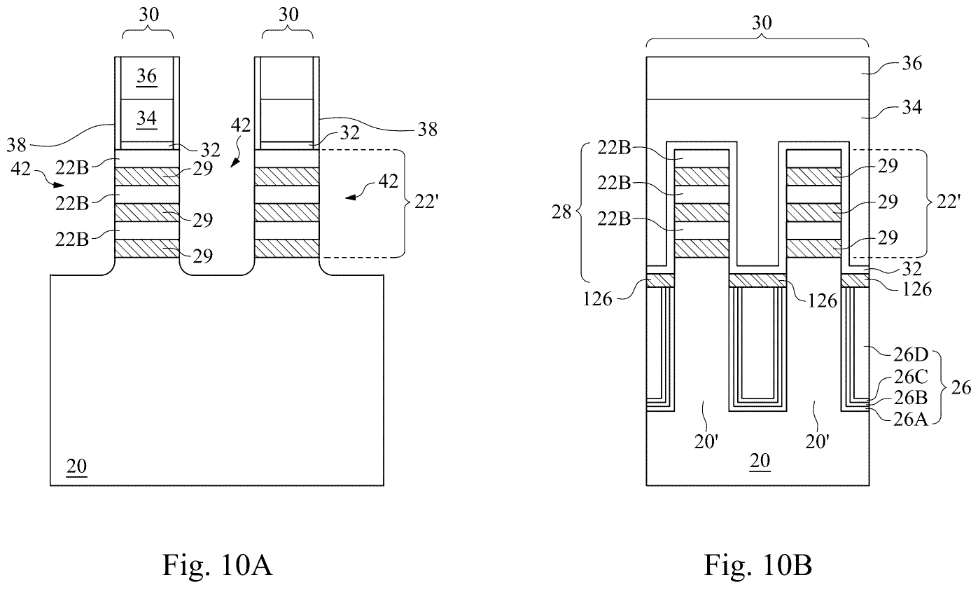

FIGS. 9A, 9B, 10A, and 10B illustrate the replacement of sacrificial layers 22A with disposable interposers 29. Referring to FIGS. 9A and 9B, which illustrate the cross-sections B-B and A2-A2, respectively in FIG. 7A, the sacrificial layers 22A are first removed, forming openings 27 between nanostructures 22B. The respective process is illustrated as process 216 in the process flow 200 as shown in FIG. 18.

Referring to FIGS. 10A and 10B, disposable interposers 29 are formed between nanostructures 22B. The respective process is illustrated as process 218 in the process flow 200 as shown in FIG. 18. In accordance with some embodiments, disposable interposers 29 comprise an oxide such as silicon oxide, and thus may also be referred to as Disposable Oxide Interposers (DOIs) 29. In accordance with other embodiments, disposable interposers 29 may comprise other types of dielectric materials such as AlO, SiON, SiC, SiCN, or the like.

The formation of disposable interposers 29 may include depositing a dielectric layer using a conformal deposition process, so that the dielectric layer includes some portions filling openings 27, and some other portions outside of openings 27. A trimming process, which may include an isotropic etching process, or an anisotropic etching process followed by an isotropic etching process, is then performed to etch and remove the portions of the dielectric layer outside of openings 27. The remaining portions of the dielectric layer are thus the disposable interposers 29.

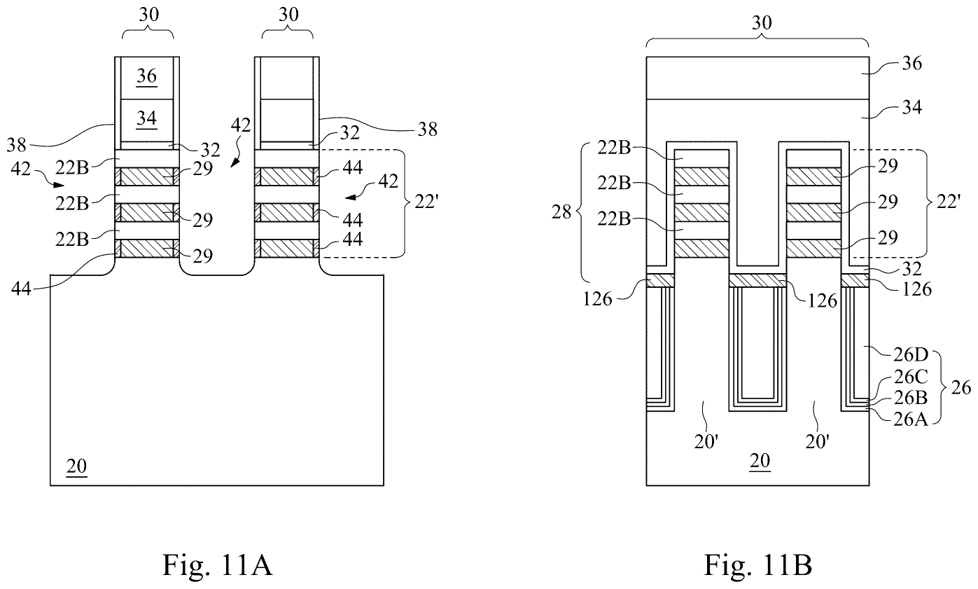

Referring to FIGS. 11A and 11B, disposable interposers 29 are laterally recessed and filled to form inner spacers 44 (FIG. 11A). The respective process is illustrated as process 220 in the process flow 200 as shown in FIG. 18. The lateral recessing of disposable interposers 29 may be achieved through a wet etching process or a dry etching process. The wet etching process may be performed using a dip process, a spray process, a spin-on process, or the like. Nanostructures 22B are not etched.

Inner spacers 44 are then formed. In accordance with some embodiments, the formation of inner spacers 44 includes depositing a conformal dielectric layer, which extends into the lateral recesses. Next, an etching process (also referred to as a spacer trimming process) is performed to trim the portions of the dielectric layer outside of the lateral recesses, leaving the portions of the dielectric layer in the lateral recesses. The remaining portions of the dielectric layer are referred to as inner spacers 44.

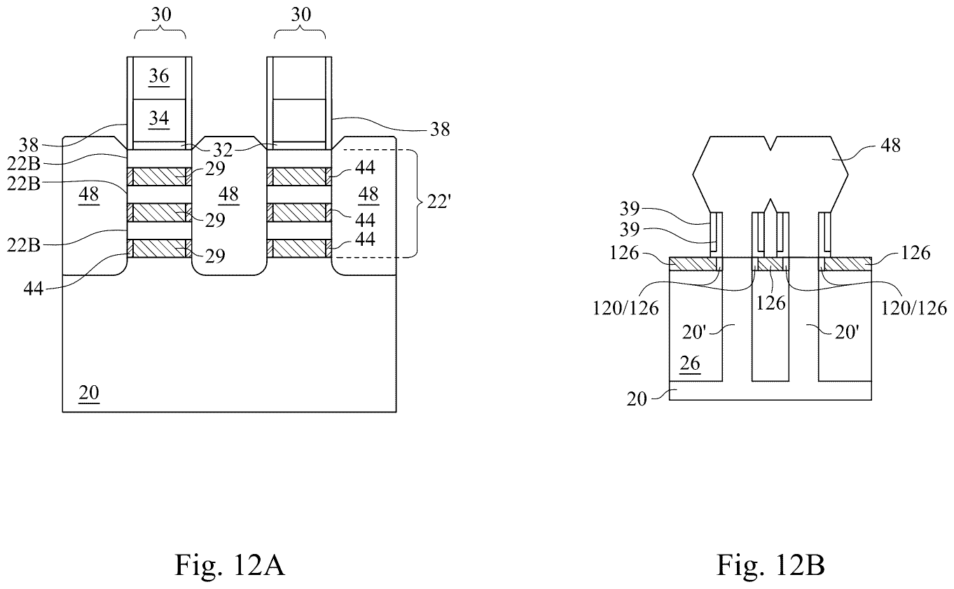

Referring to FIGS. 12A and 12B, which illustrate the same cross-sections as the cross-sections B-B and A1-A1, respectively in FIG. 7A, epitaxial source/drain regions 48 are formed in recesses 42 through selective epitaxy. The respective process is illustrated as process 222 in the process flow 200 as shown in FIG. 18. Depending on whether the resulting transistor is a p-type transistor or an n-type transistor, a p-type or an n-type dopant may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon arsenic (SiAs), silicon carbon phosphorous (SiCP), or the like may be grown.

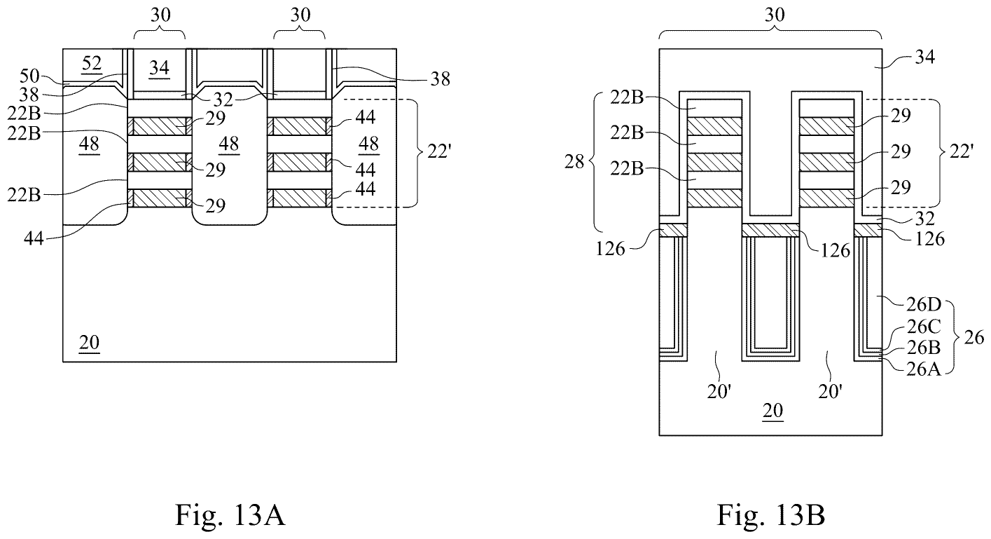

FIGS. 13A and 13B illustrate the cross-sectional views of the structure after the formation of Contact Etch Stop Layer (CESL) 50 and Inter-Layer Dielectric (ILD) 52. The respective process is illustrated as process 224 in the process flow 200 as shown in FIG. 18. FIGS. 13A and 13B illustrate the cross-sections B-B and A2-A2, respectively, in FIG. 7A. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may result in the removal of hard masks 36 to reveal dummy gate electrodes 34, as shown in FIGS. 13A and 13B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

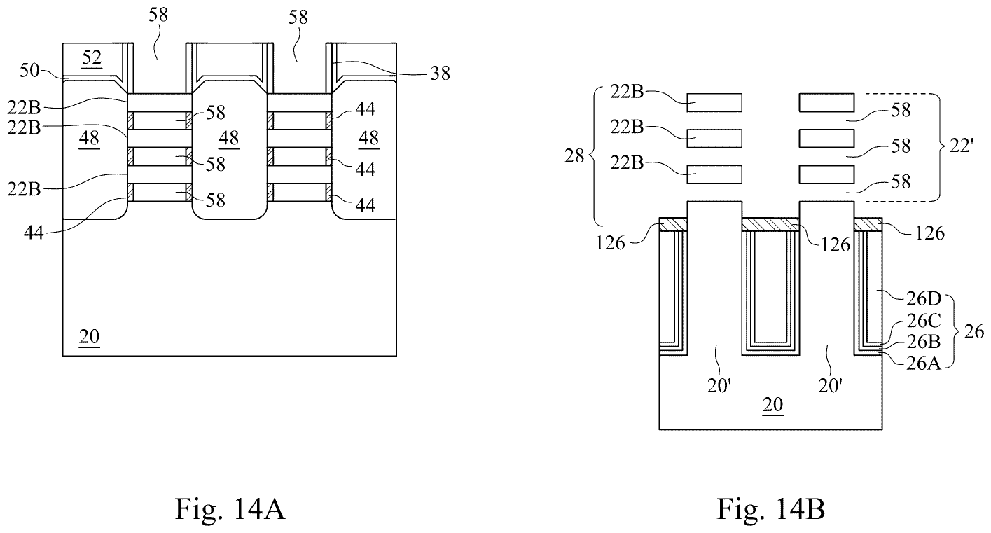

Next, dummy gate electrodes 34 and dummy gate dielectrics 32 (and hard masks 36, if remaining) are removed in one or more etching processes, so that recesses 58 are formed, as shown in FIGS. 14A and 14B. The respective process is illustrated as process 226 in the process flow 200 as shown in FIG. 18. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Disposable interposers 29 are then removed to extend recesses 58 between nanostructures 22B. The respective process is illustrated as process 228 in the process flow 200 as shown in FIG. 18. Disposable interposers 29 may be removed by performing an isotropic etching process such as a wet etching process or a dry etching process using etchants that are selective to the materials of disposable interposers 29, while nanostructures 22B and substrate 20 remain relatively un-etched as compared to disposable interposers 29. In accordance with some embodiments in which disposable interposers 29 include, for example, silicon oxide, the mixture of NF₃ and NH₃, the mixture of HF and NH₃, or HF may be used to remove disposable interposers 29.

In the etching of disposable interposers 29, as shown in FIG. 14B, the STI regions 26 are protected from the etching chemical by protection layer 126, which etching chemical is used for removing disposable interposers 29. Accordingly, STI regions 26 are not etched (or substantially not etched, for example, with the loss smaller than about 2 Å) due to the high etching selectivity, which is the ratio of the etching rate of disposable interposers 29 to the etching rate of the protection layer 126. For example, the etching selectivity may be greater than about 5, greater than about 10, greater than about 20, or higher.

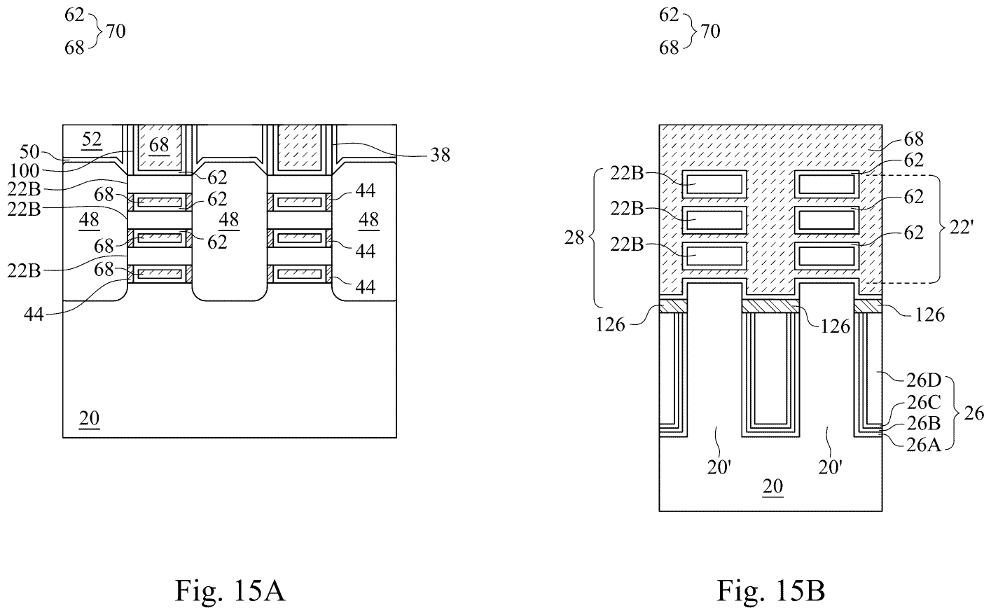

Referring to FIGS. 15A and 15B, gate dielectrics 62 and gate electrodes 68 are formed, hence forming replacement gate stacks 70. The respective process is illustrated as process 230 in the process flow 200 as shown in FIG. 18. In accordance with some embodiments, each of gate dielectric 62 includes an interfacial layer and a high-k dielectric layer over the interfacial layer. The interfacial layer may be formed of or comprises silicon oxide, which may be deposited (or formed through thermal oxidation) through a conformal deposition process such as ALD or CVD, or through an oxidation process. In accordance with some embodiments, the high-k dielectric layers comprise one or more high-k dielectric layers. For example, the high-k dielectric layer(s) may include a metal oxide or a silicate of hafnium, aluminum, zirconium, lanthanum, manganese, barium, titanium, lead, and combinations thereof.

When the interfacial layer is formed through deposition, the top surface of protection layer 126 contacts the bottom surface of the interfacial layer to form interfaces. When the interfacial layer is formed through thermal oxidation, the top surface of protection layer 126 contacts the bottom surface of the high-k dielectric layer to form interfaces.

Gate electrodes 68 are also formed. In the formation process, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′.

After the filling of recesses 58, a planarization process such as a CMP process or a mechanical grinding process is performed to remove the excess portions of the gate dielectrics 62 and gate electrodes 68, which excess portions are over the top surface of ILD 52. Gate electrodes 68 and gate dielectrics 62 are collectively referred to as gate stacks 70 of the resulting transistors.

In the processes shown in FIGS. 16A, 16B, and 16C, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 16A, 16B, and 16C, ILD 76 is deposited over ILD 52 and over gate masks 74. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

ILD 76, ILD 52, CESL 50, and gate masks 74 are then etched to form recesses (occupied by contact plugs 80A and 80B) exposing surfaces of source/drain regions 48 and/or gate stacks 70. Although FIGS. 16A illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. Contact plugs 80B are then formed over silicide regions 78. Also, contacts 80A (may also be referred to as gate contact plugs) are formed in the recesses, and are over and contacting gate electrodes 68. The corresponding structure is also shown in FIG. 16A. Transistor 82 is thus formed.

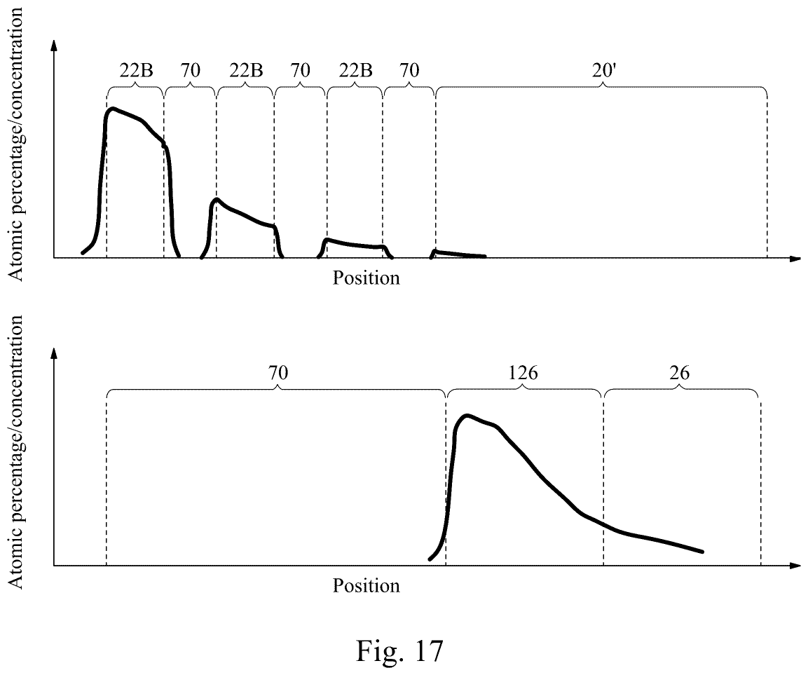

FIG. 17 illustrates some example distribution profiles of the concentrations (or atomic percentages) of the dopant introduced by doping process 124 (FIG. 4) in accordance with some embodiments. The dopant profiles represent the profiles caused by implantation process 124, due to which the implanted dopant has certain distribution (such as Gaussian distribution), with some ions/atoms of the dopant being implanted deeper than others. It is appreciated that the illustrated concentrations reflect the trend, rather than the actual concentrations.

The upper graph illustrates the concentrations (or atomic percentages) of the dopant along the path represented by arrow 84A as shown in FIG. 16B. The lower graph illustrates the concentrations (or atomic percentages) of the dopant along the path represented by arrow 84B (FIG. 16B). The position of the upper graph corresponds to the respective positions in the lower graph. Each of the upper graph and the lower graph illustrates the concentrations (or atomic percentages) of the dopant as functions of positions along the arrows 84A and 84B.

As shown in the upper graph, since the dopant may be implanted into sacrificial layers 22A (FIG. 4), which are later removed and replaced with gate stack 70 (FIG. 16B), gate stack 70 has abruptly reduced dopant concentration than the respective overlying and underlying semiconductor strips 20′. The upper nanostructures 22B have higher concentrations than the respective underlying nanostructures 22B. Also, the contour of the concentrations in nanostructures 22B may fit a curve. The peak concentration may be inside the top nanostructure 22B, and may be close to the top surface of the top nanostructure 22B.

The lower graph shows that the peak concentration of the dopant is in protection layer 126, and may be close to the top surface of protection layer 126, or at the middle between the top surface and the bottom surface of protection layer 126.

The embodiments of the present disclosure have some advantageous features. By forming a protection layer on top of the STI regions, during the removal of the disposable interposers, the protection layer protects the STI regions from being recessed in accordance with some embodiments. The undesirable increase in the parasitic capacitance between gate electrodes and semiconductor strips is thus reduced.

In accordance with some embodiments of the present disclosure, a method comprises forming a shallow trench isolation region aside of a protruding fin, wherein the protruding fin comprises a first semiconductor nanostructure and a second semiconductor nanostructure; performing a doping process to dope a dopant into a top portion of the shallow trench isolation region to form a protection layer; forming a dummy gate stack over the protruding fin; removing a sacrificial layer in the protruding fin to leave a space between the first semiconductor nanostructure and the second semiconductor nanostructure; forming a disposable interposer in the space; removing the dummy gate stack; performing an etching process to remove the disposable interposer using an etchant, wherein in the etching process, the protection layer is exposed to the etchant; and forming a replacement gate stack, wherein a portion of the replacement gate stack is filled in the space.

In an embodiment, during the doping process, the shallow trench isolation region is exposed. In an embodiment, the method further comprises forming a hard mask over the protruding fin, wherein during the doping process, the hard mask is doped with the dopant. In an embodiment, the method further comprises, after the doping process, removing the hard mask. In an embodiment, the doping process comprises doping nitrogen. In an embodiment, the doping process is performed using a process gas comprising N₂, N₂O, or a combination thereof.

In an embodiment, the dopant comprises an n-type or a p-type dopant. In an embodiment, the method further comprises forming a source/drain region aside of the dummy gate stack, wherein the dopant has an opposite conductivity type than the source/drain region. In an embodiment, the doping process comprises an implantation process. In an embodiment, the doping process comprises a plasma treatment process. In an embodiment, the doping process is performed at a temperature higher than a room temperature. In an embodiment, the doping process is performed before the dummy gate stack is formed.

In accordance with some embodiments of the present disclosure, a structure comprises a semiconductor strip; a first semiconductor nanostructure overlapping, and spaced apart from, the semiconductor strip; a shallow trench isolation region contacting an edge of the semiconductor strip; a gate stack comprising a first portion and a second portion, wherein the first portion is between the first semiconductor nanostructure and the semiconductor strip, and wherein the gate stack comprises a gate dielectric and a gate electrode over the gate dielectric; and a protection layer between the shallow trench isolation region and the second portion of the gate stack, wherein the protection layer comprises a dielectric material different from materials of the shallow trench isolation region and the gate dielectric.

In an embodiment, the protection layer comprises a dopant, and dopant concentrations of lower portions of the protection layer are lower than respective upper portions of the protection layer. In an embodiment, a bottom portion of the shallow trench isolation region comprise silicon oxide, and the protection layer comprises silicon oxynitride. In an embodiment, a bottom portion of the shallow trench isolation region comprise silicon oxide, and the protection layer comprises silicon carbonitride. In an embodiment, the protection layer comprises a n-type dopant or a p-type dopant.

In accordance with some embodiments of the present disclosure, a structure comprises a semiconductor substrate; a shallow trench isolation region in the semiconductor substrate, wherein a portion of the semiconductor substrate is aside of and contacts the shallow trench isolation region to act as a semiconductor strip; a semiconductor layer overlapping the semiconductor strip; a gate stack over and encircling the semiconductor layer; a source/drain region aside of the gate stack; and a dielectric protection layer over and contacting the shallow trench isolation region, wherein the dielectric protection layer comprises a first portion directly underlying the gate stack, and a second portion directly underlying the source/drain region.

In an embodiment, the dielectric protection layer contacts a gate dielectric of the gate stack. In an embodiment, the dielectric protection layer comprises a dopant, and wherein a first concentration of a lower portion of the dielectric protection layer is lower than a second concentration of an upper portion of the dielectric protection layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. (canceled)

2. A method comprising:
forming a shallow trench isolation region aside of a protruding fin, wherein the protruding fin comprises a first semiconductor nanostructure and a second semiconductor nanostructure over the first semiconductor nanostructure;
performing a doping process to dope a dopant into a top portion of the shallow trench isolation region as a protection layer;
performing an etching process to remove a disposable interposer between the first semiconductor nanostructure and the second semiconductor nanostructure using an etching chemical, wherein the etching chemical is configured so that:
the shallow trench isolation region has a first etching rate in response to the etching chemical; and
the protection layer has a second etching rate in response to the etching chemical, wherein the second etching rate is lower than the first etching rate; and
forming a replacement gate stack, wherein a portion of the replacement gate stack is between the first semiconductor nanostructure and the second semiconductor nanostructure.

3. The method of claim 2, wherein in the etching process, the protection layer is exposed to the etching chemical, and the shallow trench isolation region is separated from the etching chemical by the protection layer.

4. The method of claim 2, wherein at a time the doping process is started, the shallow trench isolation region is exposed.

5. The method of claim 2 further comprising forming a hard mask over the protruding fin, wherein during the doping process, the hard mask is doped with the dopant.

6. The method of claim 5 further comprising, after the doping process, removing the hard mask.

7. The method of claim 2, wherein the doping process comprises doping nitrogen.

8. The method of claim 7, wherein the doping process is performed using a process gas comprising N₂, N₂O, or a combination thereof.

9. The method of claim 2, wherein the dopant comprises an n-type or a p-type dopant.

10. The method of claim 9 further comprising forming a source/drain region connecting to the first semiconductor nanostructure and the second semiconductor nanostructure, wherein the dopant has an opposite conductivity type than the source/drain region.

11. The method of claim 9 further comprising forming a source/drain region connecting to the first semiconductor nanostructure and the second semiconductor nanostructure, wherein the dopant has a same conductivity type as the source/drain region.

12. The method of claim 2, wherein the doping process comprises an implantation process.

13. A method comprising:
forming a semiconductor strip;
forming a semiconductor nanostructure overlapping the semiconductor strip;
forming a shallow trench isolation region contacting an edge of the semiconductor strip;
forming a dummy gate stack over the semiconductor strip;
converting a top portion of the shallow trench isolation region into a protection layer; and
replacing the dummy gate stack with a replacement gate stack, wherein the protection layer is between, and is in physical contact with, the replacement gate stack and the shallow trench isolation region.

14. The method of claim 13 further comprising performing an etching process to remove a sacrificial layer between the semiconductor strip and the semiconductor nanostructure, wherein in the etching process, the protection layer separates the shallow trench isolation region from an etching chemical used for the etching process.

15. The method of claim 14, wherein the etching chemical is configured so that:
the shallow trench isolation region has a first etching rate in response to the etching chemical; and
the protection layer has a second etching rate in response to the etching chemical, and the second etching rate is lower than the first etching rate.

16. The method of claim 13, wherein the converting the top portion of the shallow trench isolation region comprises implanting a dopant into the top portion of the shallow trench isolation region.

17. The method of claim 13, wherein the converting the top portion of the shallow trench isolation region comprises diffusing a dopant into the top portion of the shallow trench isolation region.

18. The method of claim 13, wherein the protection layer has a higher nitrogen atomic percentage than the shallow trench isolation region.

19. A method comprising:
forming a shallow trench isolation region in a semiconductor substrate, wherein a portion of the semiconductor substrate is aside of and contacts the shallow trench isolation region to act as a semiconductor strip, and wherein the semiconductor strip is overlapped by a semiconductor nanostructure;
forming a source/drain region aside of the semiconductor nanostructure and the semiconductor strip;
removing a dummy gate stack over the semiconductor nanostructure to form a recess;
removing an oxide sacrificial layer between the semiconductor nanostructure and the semiconductor strip to extend the recess downwardly, wherein the removing is performed using an etching chemical, wherein the oxide sacrificial layer is removed through the recess, and wherein during the removing, an entirety of the shallow trench isolation region is separated from the etching chemical by a protection layer; and
forming a replacement gate stack in the recess.

20. The method of claim 19, wherein the etching chemical is configured to etch the protection layer slower than the shallow trench isolation region.

21. The method of claim 19 further comprising adding an element into a top portion of the shallow trench isolation region to form the protection layer.
